(19) United States
(12) Patent Application Publication
(10) Pub. No.: US 2008/0296758 A1
(43) Pub. Date: Dec. 4, 2008

(54) Protection and Connection of Devices Underneath Bondpads

(75) Inventor: Dolly Y. Wu, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/755,166

(22) Filed: May 30, 2007

(51) Int. Cl. H01L 23/52; H01L 21/44

(52) U.S. Cl. 257/737; 438/612; 257/E23.141; 257/E21.476

(57) ABSTRACT

A circuit structure and a method for reducing stresses on semiconductor devices fabricated underneath bondpads include metal layers with a lattice planar configuration which spreads forces applied such as during wafer test probing or during wire bonding. Easing electrical connectivity among circuit elements and maintaining circuit performance is also carried out using the lattice. The lattice has metal strips which may connect circuit elements together or which may connect to a reference voltage source. The metal layer and bondpad corners and edges are formed preferentially without acute angles.

### CROSS-REFERENCES TO RELATED APPLICATIONS

Not Applicable.

### STATEMENT REGARDING FEDERALLY SPONSORED RESEARCH OR DEVELOPMENT

Not Applicable.

### FIELD OF THE INVENTION

The present embodiments relate to semiconductor technology and circuits such as on a chip (IC) and are more particularly directed to reducing stresses, easing electrical connectivity and maintaining performance when devices are fabricated underneath bondpads.

### BACKGROUND OF THE INVENTION

Electronic circuits generally include large components such as passive elements like capacitors and resistors, and active elements like electrostatic discharge (ESD) protection and transistors. On an integrated circuit, particularly on a semiconductor chip, the die area is a large part of the manufacture cost of the product. Input/output (I/O) bondpads transfer signals onto and off of the chip and they occupy a large fraction of the die area and may even limit how small the die can physically be. Each bondpad is at least about 60 um×60 um in size and there are typically about 10 to over 100 of them forming a ring around a small analog circuit to a large mixed signal circuit, respectively. A bondpad is generally an overlay of one or more metal layers and is situated above an oxide layer on top of bulk silicon. There is much “wasted space” underneath a bondpad. Placing circuit elements underneath a bondpad would occupy that “wasted space” and thus reduce die area. Unfortunately, the circuit elements tend to get damaged when placed underneath a bondpad.

By being near the periphery of the die, bondpads are already located in the most easily stressed region of the die such as when individual die are cut out from a big wafer and the die is physically picked up by the edges. Bond wiring or solder balling heat and forces are applied to the bondpad to make a conductive connection between the die and the package pin leads. Worst of all, test probes may be landed on bondpads before packaging and assembly, whereby for many higher performance analog products, the die is functionality tested or calibrated. Many of the test probe tips concentrate a very large pressure (force/area) on a particularly small spot of the bondpad, and thus protrude into or crack anything underneath the bondpad. Therefore, placing circuit elements underneath a bondpad tends to harm the circuit. Placing more sensitive objects such as ESD or, say, feedback resistors of an amplifier underneath bondpads is seldom, if ever, done.

By way of specific example to the preceding, FIG. 2 shows an ESD cell with very large transistors 210 and 220 that are used to protect an input or output of a circuit; the very nature of an ESD protection makes it very sensitive to stress. Multiple fingers of an ESD cell are suppose to evenly distribute and/or absorb the current from a large current spike; but if the cell is stressed, the current absorption is uneven and the ESD no longer protects properly. However, ESD are such large objects it would be quite a die savings to be able to place them underneath bondpads. As another example, FIG. 3 shows an amplifier 310 with a gain resistor R10 and feedback resistor R20. These resistors are physically very large to avoid electromigration and to improve matching. Much area may be saved if they can also be placed underneath bondpads.

Even if less sensitive circuit elements are placed underneath bondpads to avoid harming the overall circuit, there is still the problem of connectivity. It is more difficult to connect the circuit element with the rest of circuit if the element is underneath a bondpad. The connectivity (e.g. metal wire, via) itself is now in a region that can easily be damaged because at least some portion of the connection is underneath the bondpad that will suffer the various stresses and pressures described above. Worse still, a metal wire or via would itself create a new stresses on the device underneath it, when force is transferred from the bondpad to the metal wire or via.

Since a major purpose of putting circuit devices underneath bondpads is to save die area and costs, an important consideration is how to make a protection structure cost-effectively. If new material is introduced or even an additional mask step added to where it did not exist before, the extra cost defeats the purpose of putting objects underneath bondpads. Moreover, additional or new layers add to the risk of manufacture and generally reduce the fabrication yield of the product, again driving up costs.

Even if test probes, package assembly or other forces do not harm or stress the devices underneath bondpads, there is another problem to be considered. Placing objects under bondpads may also affect the bondpad itself, or the interaction between the bondpad and the circuit device underneath may alter the overall chip performance. This too translates into a reduction of manufacture yield: if the circuit does not perform up to specification requirements, it is thrown out or sold as a lower quality product at a lower cost. This is one of the most important concerns of high end products and high performance chips.

In view of the above issues, there arises a need to address the drawbacks of the lack of art to protect and connect to devices underneath bondpads, as is achieved by the preferred embodiments described below.

### BRIEF SUMMARY OF THE INVENTION

Avoid legal hassles by not including such a section.

### BRIEF DESCRIPTION OF THE DRAWINGS

FIG. 1 illustrates an example snowshoe.

FIG. 2 illustrates an example ESD (electrostatic discharge device) structure with transistors which use the invention.

FIG. 3 illustrates an example amplifier with resistors which uses the invention.

FIG. 4 illustrates a top view of a bondpad with protection structure underneath according to one embodiment of the invention.

FIG. 5 illustrates a side view of a bondpad with protection and a device underneath according to one embodiment of the invention.

FIG. 6 illustrates an example circuit and layout which uses the invention.

FIG. 7 illustrates another example circuit and layout which uses the invention.

### DETAILED DESCRIPTION OF THE INVENTION

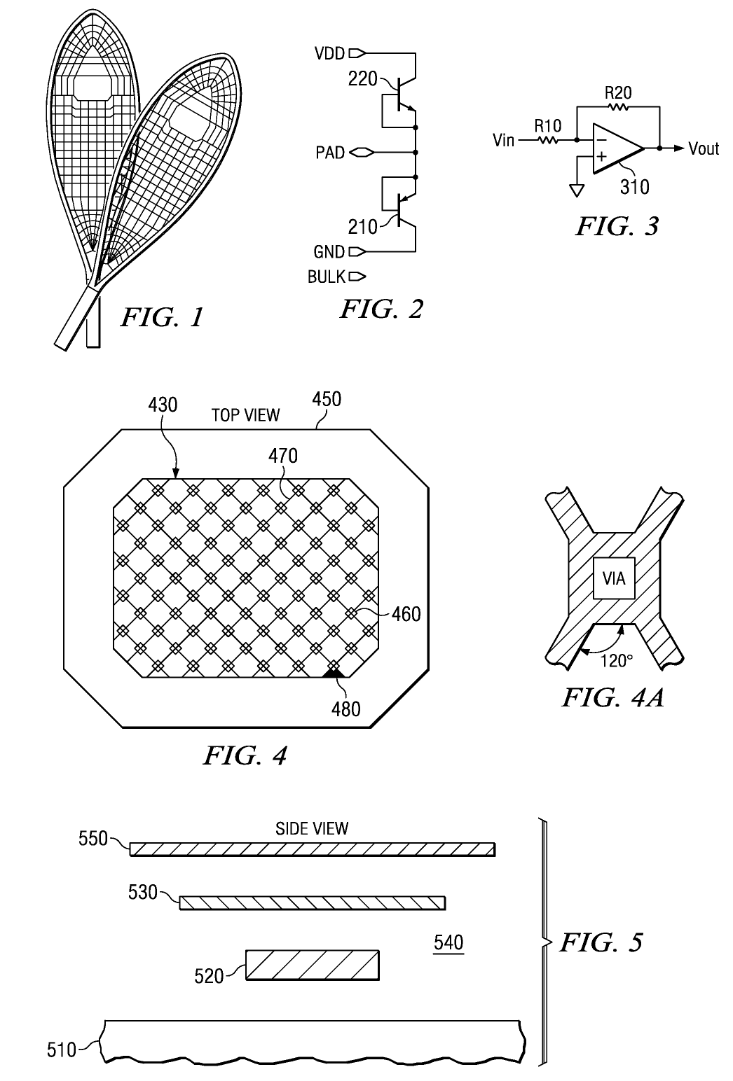

FIG. 1 shows an example of snowshoes used by Maine Indians in America with a grid-like structure of rope or cloth material strung across a wooden frame. The snowshoe is light-weight and flexible because it is not made of a rigid, solid material. However, it withstands much pressure, allowing a person carrying heavy loads to run across snow without sinking into the snow. Therefore, the snow underneath the snowshoe is not crushed and compacted the way snow would crumble underneath someone treading on it with ordinary shoes. The planar area of the grid-like (waffle) structure is much larger than the planar area of a foot of a person and the force (weight of the person) is distributed over a larger area with the grid-like snowshoe even though the strands of rope/cloth are rather thin and narrow. The concept of a snowshoe is generally considered for the invention of this application. A grid-like (lattice) protective structure is preferentially superposed over a circuit device or an array of devices and both the protective structure and devices are fabricated underneath a bondpad. The lattice structure spreads the force due to heat and mechanical stresses applied on the bondpad during, say, wafer test, die sawing, assembly or packaging. FIG. 5 shows a side view of such a stack of objects. Element 510 is a substrate, 520 is a device, 530 is a protective grid-like structure, 540 is a surrounding oxide material such as SiO₂, and 550 is a bondpad. Different embodiments of these general structures are described in detail in subsequent paragraphs. The grid-like structure is preferentially constructed from the existing layers of material for a particular technology used to fabricate a circuit and chip. The grid-like structure may generally be used as part of the connectivity structure to connect the device to the rest of the circuit components on the chip. The interaction between the bondpad, protection structure and device are additional considerations in the embodiments of the invention described below.

Placing non-critical circuit devices underneath bondpads to save die may be done with less risk of damaging the performance of the chip than placing critical elements. For example, non-critical by-pass capacitors used between the power supplies to damp out noise may be placed underneath bondpads. However, many products do not need such capacitors or do not have enough of them; so, there are still bondpads remaining with no circuit devices underneath them and die area being wasted to place the devices elsewhere. On the other hand, nearly all chips have ESD circuits to protect the core circuit from electrostatic discharge and large currents damage. There are typically as many ESD structures as there are bondpads, except for the few bondpads devoted to a reference supply, such as ground. Moreover, ESD structures are usually placed adjacent to the input/output bondpads of a chip to absorb the large currents before the current can reach the core. Therefore, ESD structures are natural candidates to be placed underneath bondpads.

As mentioned in the Background discussion, ESD cells are quite sensitive to damage and stress and placing them underneath bondpads would only increase the chance of their being stressed. Therefore, it would be very beneficial to have some sort of protective structure between the ESD cell and the bondpad. An example of ESD is shown in FIG. 2, with two large Off-transistors used as diodes, one 220 between the PAD and VDD electrical nodes, and the other 210 between the PAD and GND electrical nodes. ESD structures are typically somewhat smaller than the size of an average bondpad, but may also be even bigger than a bondpad. The ones smaller than a bondpad are preferentially placed underneath a bondpad. In an alternative embodiment, a bondpad may be over-sized so that it would entirely cover over an ESD structure. For example, a large rectangularly-shaped bondpad rather than a symmetrical, square-shaped bondpad may be used. In such a case, the protective structure would also be re-shaped accordingly.

An array of devices may also be placed under a bondpad. For example, FIG. 3 shows an amplifier with resistors R10 and R20. For matching purposes, the resistors are sized very large using many squares (sheet resistance is in the units of Ohms/square) and the head and via connection resistances are mitigated as much as possible. “Single” resistors like R10 and R20 are often actually several unit resistors connected in series. Placing an array of devices that need to be matched has the additional problem of maintaining the matching. Therefore, under such a circumstance the grid-like planar protective structure superposing the array of devices would generally have to be layed out and oriented in such a way as to preserve symmetry. The grid slats, for example, would superpose each device in such a way that each device has the same surrounding environment and objects (e.g. via) as a neighboring device in the array. An array of devices may also occupy so much area that some of the devices may go beyond the planar area (dimensions) of the bondpad and protective structure. In such a case, it would be better to place the dummy devices directly below where the edge of, say, the protective structure exists. The dummy devices are the elements on the periphery of the array so that the more centralized elements maintain a uniform surrounding environment. Alternatively, the bondpad and associated protective structure can be re-dimensioned and oversized to cover over the array of devices. If the array is still too large, it would be better not to put the array underneath a bondpad unless its location does not affect the chip performance and the integrity of the overlying bondpad is not compromised.

According to a first embodiment of the invention illustrated in FIGS. 4 and 5, the protective grid-like (waffle) structure 430 or 530 is made of conductive metal, preferentially lower level metal such as M1 or M2. M1 and M2 are the two metal layers nearest to the poly layers of the technology used to fabricate the transistors. Conventionally, all the existing metal layers for a technology are numbered from bottom (substrate) to top (die surface). These conductive metal layers are preferentially the same metal layers which naturally exist in the mask layers of most semiconductor manufacturing technologies and therefore the protective structure is fabricated without incurring extra costs. If the technology supports many metal layers, then M3 metal layer, and so on, may also be used in addition to M1 and M2. The grid lines 470 are conductive metal and the joining elements where the lines cross are vias or contacts 460. (The word ‘vias’ is used to include contacts which are typically the type of vias used between poly and metal, and regular vias are normally between metal and metal.) The vias are optional if the device 520 does not need to have interconnections within itself or to connect to other circuitry, such as to the core circuitry on the chip. The vias are spread throughout the protective structure to distribute stresses evenly. Though illustrated as a drawing line 470, these metal grid lines are preferentially wider than the minimum width allowed for that metal layer. For example, if the design rule for M1 is at least 0.5 um, then the metal width in the protective structure is preferentially at least double that, say, 1 um wide. The metal grid lines should also be wider than the width of the vias in order to improve yield. There may also be more than one via at each corner where the grid lines cross, or even many vias along the length of the metal strips.

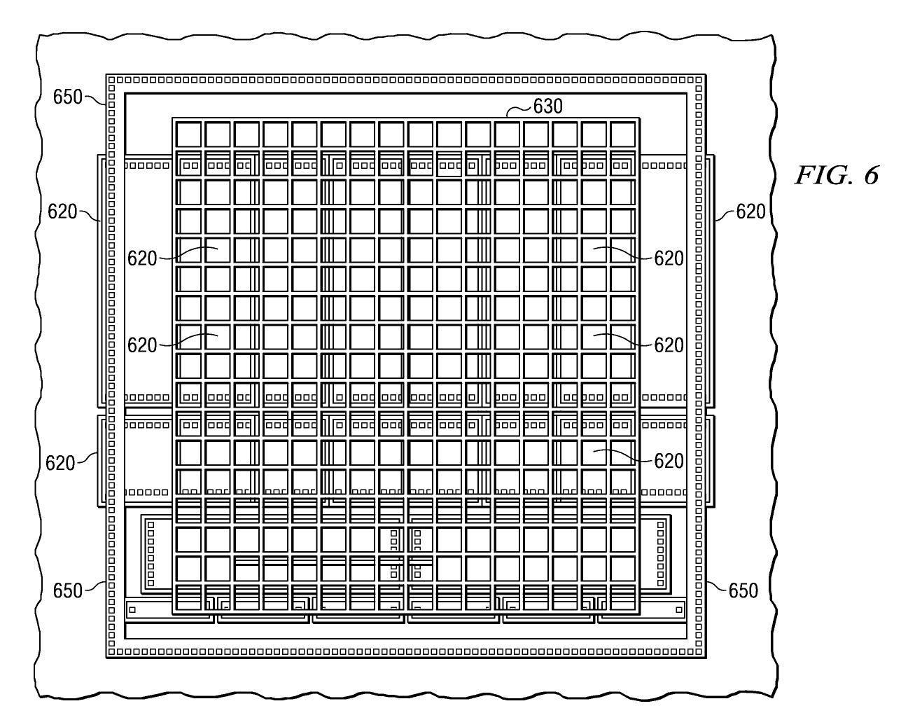

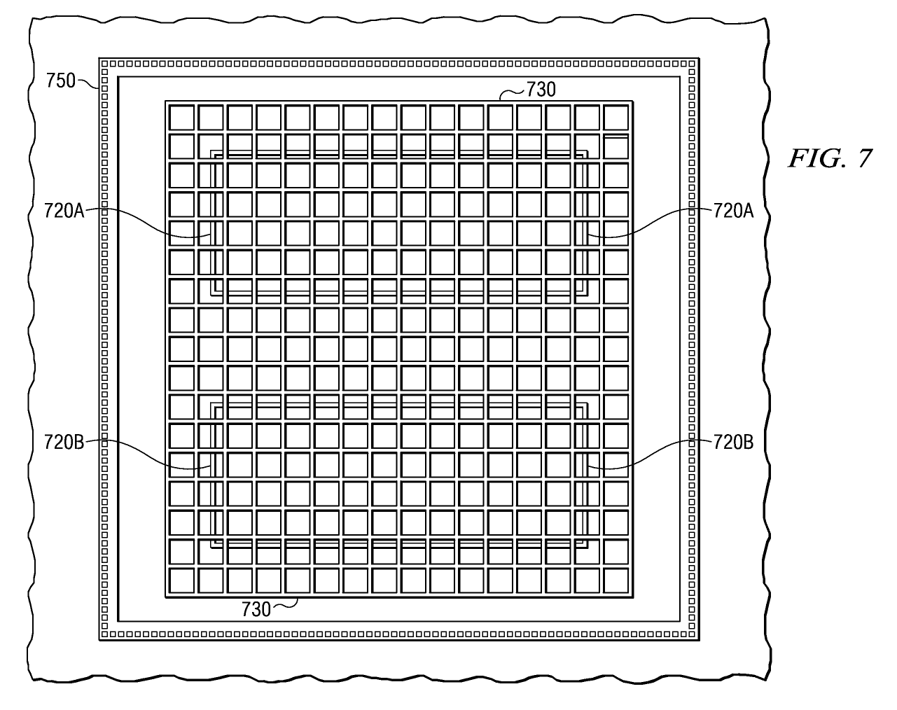

Conductive metal congregates charge at the surface boundary and at sharp corners and edges. There will be a corresponding high electric field associated with the charge. In addition, sharp edges are difficult to manufacture evenly and consistently. Therefore, where the grid lines (metal strip) meet and cross one another, electrically shorting together on a plane, the corners are preferentially beveled to be greater than 90 degrees (obtuse angle). So metal strips are not crossing and shorting at 90 degrees, but at say, 120 degrees, such as illustrated in FIG. 4A. Rounded or curved corners may be even better; however, the layout editor tools generally do not permit such a construction. The high electric fields are generally dynamic because charge is being re-distributed continuously. There are also electromagnetic fields from the protected device 520 and from the bondpad 450 or 550, as current travel to and from these elements. Existence of electromagnetic interference (EMI) tends affect the chip performance adversely or contribute to the EMI emissions of the chip. Since EMI is greater at acute angles (sharper angles and edges less than 90 degrees), intersections of a conductive material, metal strip crossings, corners of the conductive metal and vias, as well as the conductive bondpad portions 5, are preferentially beveled or rounded as illustrated in the top views FIG. 4 and 4A in order to reduce EMI. Obtuse angles are preferred. The peripheral boundary (border) of the protective structure 430 is preferentially beveled as well in FIG. 4—the corners are beveled. In addition, the peripheral boundary of the bondpad 450 is also preferentially beveled so that there are no acute angles. Normally bondpads 650 and 750 have orthogonal boundaries such as depicted in FIGS. 6 and 7. However, since a device 520 is now underneath the bondpad, more care is needed to avoid interference between the bondpad and the device underneath. Therefore, increased EMI resulting from acute angles should be avoided.

As depicted in FIG. 4, the metal grid terminates on the peripheral boundary of the planar protective structure 430. Depending on the choice of metal strip spacing, width of the metal strip, the termination may create an acute angle, such as in the example at the vicinity of 480. If it is deemed necessary to avoid acute angles there, the small area may be filled completely with metal, or the acute angles have some small metal fill to change corner angles to be greater than 90 degrees (obtuse angle). It may not be necessary to do anything if the device being protected 520 is small relative to the size of the protect structure 530, as in the example of FIG. 5. Then, the device is sufficiently far from the edge of the structure 530 that the effect of the electric fields may already be reduced. In addition, the edge of the structure 530 produces other effects which may be more of a concern than the dynamic or static electromagnetic field effects. The mechanical stress is greatest near the edges of an object where the stress will increase sharply right at the edge and then peter down again, once past the edge. This stress may alter the device or bondpad during manufacture and assembly sufficiently to affect the performance of the chip. The mechanical stress, however, is not generally dynamic, the way the electrical effects are.

The orientation of the metal strips in the protective structure 530 depends on the orientation and nature of the device underneath being protected. If the metal strips are oriented parallel to the edge of the protective structure, then there is little in the way of termination problems. The angle where the strips terminate at the periphery of 530 would be 90 degrees generally, except for the small region near the beveled corners, where the angle may be less than 90 degrees. If the protective structure is also used as interconnect, the orientation of the metal strips should preferentially follow the orientation of the vias and contacts which are needed to connect to the device.

Since a device 520 (FIG. 5) is now underneath the bondpad, more care is needed to avoid interference between signals on the bondpad and the device underneath. For example, if the protected object 520 carries a signal and the bondpad is carrying a similar signal, the interference between the two signals increases jitter or ISI (intersymbol interference). If the protect structure 530 is not used as interconnect between the device 520 and the core circuit or another circuit such as another device underneath another bondpad, then the metal may be connected to some reference voltage such as ground. Having a reference or ground plane shield between the device and the bondpad is an effective way to isolate the signals on the bondpad and on the device. Alternatively, more than one metal layer may be used for the protect structure 530. For example, some technologies have four (M1 through M4) or more aluminum metal layers plus an additional copper layer at the very top. If M4 is used for the bondpad, then M1 and M2 may be used as the protective grid structure 530. Both M1 and M2 may be grounded or shorted to some reference voltage source. Or alternatively, M1 may be used for circuit interconnect (e.g. electrically short together) and M2 is used as the protective structure 530 and M2 is grounded. Therefore, depending on the number of metal layers available in a particular technology, it would be possible to use a variety of layers for the protective structure 530, have a variety of grounding schemes for one or more layers or no grounding schemes for any layer.

In a further embodiment of the invention, the metal protect structure 530 of FIG. 5 is used as both a shield to spread the force due to heat and mechanical stresses on a device 520 underneath a bondpad 550, and also used as an interconnect. For example in FIG. 2, the large ESD transistors 210 and 220 have emitter nodes which are connected to each other and the bases of the transistors are connected to the emitters. Such connections are done on metal M1 typically. If M1 is also intended to be used in the protect structure 530 as well, the protect structure would interconnect the bases and emitters. FIG. 7 shows such an example layout. The rectangularly-shaped transistors 720A and 720B correspond to the transistors in the ESD circuit of FIG. 2; element 730 is the protective lattice structure and 750 is the bondpad. The transistors may be positioned to align with the metal wires of the grid 730 and vias may be placed not only where the metal of the grid crosses, but also placed along the entire length of the metal where the metal superpose the emitter or base of the transistors. The metal wire may be sized optimally to align or match the width of the transistor fingers where the emitter and bases are. The metal grid would preferentially have wide enough metal to avoid current crowding and electromigration during an ESD event or high current surge. The metal may be beefed up (i.e. carry more current) by using and shorting through connections (e.g. vias) to an additional metal layer M2, for example. The metal for the PAD node of FIG. 2 is the bondpad itself; so an array of vias and thick metal can connect from the devices right up to the bondpad itself. This is convenient and also reduces the resistive drop that a current surge has to traverse. Depending on the configuration of the ESD transistors, a number of possibilities exist for the configuration of the protective device 730. A separate metal layer is needed to connect the collectors of the ESD transistors to the power supply node VDD and the ground node GND. An additional grid-like planar metal layer, M2 or M3, is preferentially used and it is offset from the grid of layer M1. Alternatively, the protective structure 730 may have been constructed from two layers, M1 metal strips traversing a horizontal direction and M2 or M3 metal strips traversing a vertical direction. As another preferred alternative, M1 may be used purely for interconnect purposes and not for protective shielding and M2 or M3 is used to construct the protective grid. Then M1 is run all the way to the edge of the bondpad, going past the edges and boundary of the planar protective structure 730. Then M1 is via connected up to the bondpad near the edges of the bondpad as shown in FIG. 7, where there is a ring of vias (there are actually more than one row of vias in a strip, though only one row is illustrated for visibility and clarity). So the emitters of the transistors are now connected to the node PAD, the bondpad.

FIG. 6 illustrates an embodiment with an array of passive devices placed underneath the bondpads, the resistors R10 and R20 from FIG. 3. Unfortunately not all of the resistors of the array fit neatly underneath the bondpad 650 and protect structure 630 and there is no room left for dummy resistors. In addition, the value of the resistance needs to be adjusted from one version to another version of the product. So the resistors which generally need to have good matching are placed in a symmetrical location to preserve matching among partner pairs. After wafer probe test, assembly and packaging, the measured gain of the amplifier based on the ratio of the resistors R20 and R10, is the expected value. This generally indicates that the layout symmetry is sufficient and the stresses on the protect structure 630 and bondpad 650 does not harm the resistor devices underneath. In one configuration, metal M2 is used both as interconnect and as the protect structure grid; and M1 is used as interconnect. In this example, the circuit nodes Vin and Vout do not happen to go to the bondpad which allows more flexibility. In this instance, unlike with ESD cells, the maximum current conducted through the wires is very small; so the connecting wires may be fairly narrow. This allows more flexibility in dimensioning the grid-like structure spacing, how large or small the holes in the grid may be. With larger holes, there is more flexibility in adding vias where the holes are to use for interconnect purposes. However, if the holes are too large, the grid does not deflect mechanical stresses so well. Having a solid plane as a protective structure would be generally cumbersome. First, it adds too much parasitic capacitance to the circuit, and second, it does not allow interconnections readily.

Using metal for the grid-like protective structure has several advantages. For example, it is inexpensive because it is already part of the mask layers. Additionally, it is convenient and can be used as metal interconnect from the device underneath the bondpad to circuitry located elsewhere on the chip. The advantage of using the grid-like structure for interconnect is that the forces are distributed over a wide array. Also there are many wire strips providing the connection; so, if one strip is somewhat damaged, there are many remaining strips to provide for a good connection. Prior to this invention, a rather narrow-width piece of solid wire is used to connect between circuit devices. But this solid wire would have to run underneath the bondpad itself before it reaches the other circuit element. When the bondpad is stressed, the wire underneath too can become damaged if it is thin. If the connecting wire is a wide, solid metal, it may create torsion forces when the bondpad above it is stressed. The torsion forces tend to harm the circuit. Therefore, it is preferable to use the protective structure itself as interconnect.

Further advantages of the invention include the fact that metal is malleable. It can absorb mechanical stresses, become dented without cracking and seriously harming the objects lying underneath it. The grid-like structure enhances the malleability. The protective structure may be used as an electrical shield, and not just as a mechanical shield, when it is tied to a reference voltage such as ground, isolating the bondpad signal from the signal carried by the device. If the protective structure is used as an electrical shield, it may be fine to have a solid plane rather than a grid-like plane. This would be fine particularly if the vertical distance between the protected object and the metal layer used as a shield is large. Then even if the metal layer is stressed, it would be less likely to harm the object underneath. The corners of a solid plane is preferentially beveled to reduce EMI and high fields. If the protective structure is used as an electrical interconnect and not as a planar shield, connecting between devices, it is more convenient to have a grid-like structure. Therefore, having such grid-like metal protection structure above a device is a good way to deflect stresses, provide electrical connectivity and be configured to preserve circuit performance. And placing devices underneath bondpads saves much die area and product manufacture costs.

The method for implementing the invention to reduce stress on a device underneath a bondpad is based on FIG. 5. A silicon wafer is doped to form a substrate 510, such as a p-type or n-type substrate. An epitaxial layer may be grown on the wafer and be considered as part of the substrate. Integrated circuit elements may be formed by patterning different layers on top of and in the substrate. An oxide layer 540 is generally grown on the substrate. Depending on the nature of the device 520, it is generally formed through diffusion, implantation, etching, etc. Then selected areas of the oxide may be patterned and etched to create areas where contacts may be formed to connect underlying silicon and the metal wiring above. One or more layers of metal wiring, such as aluminum, may be deposited. This mask step is the same as for forming the protective grid-like structure 530. The bondpad 550 is generally metal, upper level metal with vias and it is formed last. A protective overcoat, such as a nitride film, is deposited over the die. Windows are etched through the overcoat to expose the top of the bondpads so that bondwires may be attached to the bondpads, which are the input and output nodes of the integrated circuit on the chip. The step for depositing the metal wiring depends on the pattern generated during the layout phase of the circuit and mask design. The pattern is preferentially generated without sharp, acute angles in the metal (i.e. obtuse angles preferred) for the bondpad 550 and the protective structure 530. The protective structure may be further used as interconnect or as a grounded shield plane, or shorted to some voltage other than ground. Since the protective structure is malleable and is not solid, it creates less stress on the object underneath it. Meanwhile, it distributes pressure exerted from above on the bondpad. This is similar to the concept of the grid-like snowshoe when a person exerts pressure (weight) and the snow is not crushed downwards underneath and the person does not sink into the snow.

From the above, it may be appreciated that the preferred embodiments provide structures to protect devices fabricated underneath bondpads on an IC chip. For example, at least one layer of metal with grids is used to spread the stress (force) on the bondpads created during wafer test, package or assembly to protect the device underneath. A conductive metal structure from one of the metal layers existing for the technology can be manufactured in varying dimensions dependent upon application requirements. While the devices have been shown in a bipolar (e.g. FIG. 2) technology configuration, various alternative passive (e.g. FIG. 3) and active devices (e.g. FIG. 2) in other technologies may be placed underneath bondpads by one skilled in the art wherein these preferred embodiments may be implemented. Electrical connections are generally formed between two objects by shorting them together through some current and voltage conductors, such as vias, metal, poly, and so on. However, electrical connections may also include intermediate objects such as resistors, capacitors, etc. in this invention disclosure because the protected device is not circuit specific. Further, the words “connection”, “connected” and “connect” may include real-life physical vias, contacts, short-length metal, short-length poly and the like to physically implement the connection of two nodes (terminals) which may thus entail small voltage drops, but does not otherwise alter the intended idealness of a connection (a short) between, say, two circuit nodes such as shown on the circuit schematics of FIGS. 2 and 3. Given the preceding, therefore, one skilled in the art should further appreciate that while the present embodiments have been described in detail, various substitutions, modifications or alterations could be made to the descriptions set forth above without departing from the inventive spirit and scope, as are defined by the following claims.

What is claimed is:

1. A semiconductor structure for protecting circuit devices fabricated underneath a bondpad, comprising:
at least one metal layer formed from a group consisting of M1, M2 and M3 level metal of a semiconductor technology;
the at least one metal layer superposes the circuit devices and the bondpad superposes the at least one metal layer;
the at least one metal layer comprises metal strips forming a metal grid in each metal layer, wherein the metal strips in each metal layer are of a single metal level and the metal strips of each metal layer crosses orthogonally meeting at a corner, and the corner is beveled to form obtuse angles; and
wherein the metal grid is for reducing stresses on the circuit devices underneath.

2. The semiconductor structure of claim 1 wherein the bondpad has beveled corners and a peripheral boundary of the at least one metal layer also has beveled corners.

3. The semiconductor structure of claim 1 wherein the structure is on an IC chip, and wherein one of the at least one metal layer is used as interconnect to electrically connect the circuit devices to other circuit devices on the IC chip.

4. The semiconductor structure of claim 2 wherein the structure is on an IC chip, and wherein one of the at least one metal layer is used as interconnect to electrically connect the circuit devices to other circuit devices on the IC chip.

5. The semiconductor structure of claim 1 wherein one of the at least one metal layers is shorted to a reference voltage source.

6. The semiconductor structure of claim 2 wherein one of the at least one metal layers is shorted to a reference voltage source.

7. The semiconductor structure of claim 1 wherein the metal strips join to a peripheral boundary of the at least one metal layer without forming acute angles in metal.

8. The semiconductor structure of claim 1 wherein the circuit devices are electrostatic discharge circuits (ESD).

9. The semiconductor structure of claim 1 wherein the circuit devices are an array with matched circuit elements.

10. An integrated circuit chip with a device fabricated underneath a bondpad, comprising:
a metal layer formed from a group consisting of M1, M2 and M3 level metal of a semiconductor technology;
the metal layer superposes the device and the bondpad superposes the metal layer;
the metal layer comprises metal strips all of a same metal level forming a metal grid, wherein the metal strips of the grid crosses orthogonally;
wherein the bondpad has beveled corners and a peripheral boundary of the metal layer also has beveled corners; and
wherein the metal grid is for reducing stresses on the device underneath.

11. The integrated circuit chip of claim 10 wherein the metal layer is used as interconnect to electrically connect the device to a circuit element on the integrated chip.

12. The integrated circuit chip of claim 10 wherein the metal layer is shorted to a reference voltage.

13. The integrated circuit chip of claim 10 wherein the device is an electrostatic discharge circuit (ESD).

14. The integrated circuit chip of claim 10 wherein the device is an array with matched circuit elements.

15. The integrated circuit chip of claim 10 wherein the metal strips are wider than minimum design rule width and wider than vias for electrical interconnects.

16. A method of forming a structure to protect circuit devices fabricated underneath a bondpad, the method comprising the steps of:
forming at least one metal layer using M1, M2, or M3 level metal of a semiconductor technology;
superposing the at least one metal layer over the circuit devices;
superposing the bondpad over the at least one metal layer;
forming a metal grid in each metal layer using metal strips of a same metal level;
patterning the metal grid to form obtuse angles where the metal strips meet and cross; and
beveling a first peripheral boundary of the at least one metal layer to form obtuse angles at corners.

17. The method of claim 16 further comprising a step of:
beveling a second peripheral boundary of the bondpad to form obtuse angles at bondpad corners.

18. The method of claim 16 further comprising a step of:
using one of the at least one metal layer to as interconnect to electrically connect the circuit devices to other circuit devices on an IC chip.

19. The method of claim 16 further comprising a step of:
shorting one of the at least one metal layer to a reference voltage source.

20. The method of claim 16 further comprising a step of:
constructing an electrostatic discharge circuit (ESD) as on of the circuit devices protected by the structure.
